(19) United States
(12) Patent Application Publication
(10) Pub. No.: US 2025/0318161 A1
(43) Pub. Date: Oct. 9, 2025

(54) HIGH VOLTAGE SEMICONDUCTOR DEVICE INCLUDING BOOTSTRAP SCHOTTKY DIODE

(71) Applicant: SK keyfoundry Inc., Cheongju-si (KR)

(72) Inventor: Youngbae KIM, Sejong-si (KR)

(73) Assignee: SK keyfoundry Inc., Cheongju-si (KR)

(21) Appl. No.: 18/938,652

(22) Filed: Nov. 6, 2024

(30) Foreign Application Priority Data
Apr. 4, 2024 (KR) 10-2024-0045693

(51) Int. Cl. H01L 29/872; H01L 27/06; H01L 29/06; H01L 29/40

(52) U.S. Cl. CPC H10D 8/60; H10D 62/106; H10D 64/112; H10D 84/811

(57) ABSTRACT

A semiconductor device includes a deep n-type well (DNW) formed in a junction termination region, a source region and a drain region formed in the DNW, a source electrode electrically connected to the source region, a drain electrode electrically connected to the drain region, an anode electrode formed in a Schottky diode, a cathode electrode electrically connected to the source electrode and a first p-type guard ring surrounding the Schottky diode, the first p-type guard ring including a first p-type buried layer (PBL) and a first deep p-type well (DPW) formed on the first PBL. The first PBL extends further towards the junction termination region than the first DPW.

### CROSS-REFERENCE TO RELATED APPLICATIONS

The present application claims the benefit under 35 U.S.C. § 119 (a) of Korea Patent Application No. 10-2024-0045693 filed on Apr. 4, 2024 in the Korea Intellectual Property Office, the entire disclosure of which is incorporated herein by this reference for all purposes.

### BACKGROUND

### 1. Field

The following description relates to a high voltage semiconductor device including a bootstrap Schottky diode.

### 2. Description of the Related Art

To turn on a power semiconductor, such as an n-type metal oxide semiconductor field effect transistor (MOSFET) or an insulated gate bipolar transistor (IGBT), a high positive voltage must be applied to the gate. A bootstrap circuit can be used to apply a high positive voltage to a power semiconductor.

A bootstrap circuit may include a bootstrap diode and a bootstrap capacitor. In the bootstrap circuit, the capacitor is charged with voltage when the diode is turned on, and a power voltage as well as the voltage charged on the capacitor is applied to ensure that sufficient voltage is applied to the gate of the power semiconductor.

In one aspect, a PN diode or a Schottky diode may be used as a bootstrap diode. If a Schottky diode is used, a large amount of leakage current may be generated in the direction of the substrate of the bootstrap diode. It is also necessary to protect the bootstrap diode from high voltage to ensure that the bootstrap diode operates reliably.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Various examples of the present disclosure are designed to overcome the problems described above. It is an object of the present disclosure to provide a high voltage semiconductor device capable of reducing leakage current in the substrate direction of a bootstrap Schottky diode and protecting the bootstrap Schottky diode from the high voltage.

The technical problems that the present disclosure seeks to overcome are not limited to the technical problems described above. Other technical problems not mentioned will be apparent to those skilled in the art from the examples of the present disclosure.

In one general aspect, a semiconductor device includes: a deep n-type well (DNW) formed in a junction termination region; a source region and a drain region formed in the DNW; a source region and a drain region formed in the DNW; a source electrode electrically connected to the source region; a drain electrode electrically connected to the drain region; a drain electrode electrically connected to the drain region; an anode electrode formed in a Schottky diode; a cathode electrode electrically connected to the source electrode; and a first p-type guard ring surrounding the Schottky diode, the first p-type guard ring comprising a first p-type buried layer (PBL) and a first deep p-type well (DPW) formed on the first PBL. The first PBL extends further towards the junction termination region than the first DPW.

The semiconductor device may further include a source field plate electrically connected to the source electrode; a drain field plate electrically connected to the drain electrode; a p-type top layer (P-TOP) formed in the DNW; and a field oxide layer formed on the P-TOP.

The semiconductor device may further include a first n-type buried layer (NBL) formed in the Schottky diode; a first p-type well (PW) and a second PW formed on the first NBL; a Schottky barrier formed on the first PW and the second PW and connected to the anode electrode; and a first n-type well (NW) formed on the first NBL and connected to the cathode electrode. The first NW, the first PW and the second PW may overlap the first NBL.

The semiconductor device may further include an n-type guard ring disposed adjacent to the first p-type guard ring and comprising a second NBL and a third n-type well (NW) formed on the second NBL; and a second p-type guard ring disposed adjacent to the n-type guard ring and comprising a second PBL and a second DPW formed on the second PBL.

The first PBL, the second NBL and the second PBL may be formed in parallel with each other.

The first PBL may have a length greater than a length of the second PBL.

In another general aspect, a semiconductor device includes: a deep n-type well (DNW) formed in a junction termination region; a source region and a drain region formed in the DNW; a source electrode electrically connected to the source region; a drain electrode electrically connected to the drain region; an anode electrode formed in a Schottky diode; a cathode electrode electrically connected to the source electrode; a first deep trench and a second deep trench formed to surround the Schottky diode; and a first p-type well (PW) and a first highly doped p-type (P+) region formed in the DNW and disposed between the source region and the first deep trench.

The semiconductor device may further include a source field plate electrically connected to the source electrode; a drain field plate electrically connected to the drain electrode; a p-type top layer (P-TOP) formed in the DNW; and a field oxide layer formed on the P-TOP.

The semiconductor device may further include a first n-type buried layer (NBL) formed in the Schottky diode; a first p-type well (PW) and a second PW formed on the first NBL; a Schottky barrier formed on the first PW and the second PW and connected to the anode electrode; and a first n-type well (NW) formed on the first NBL and connected to the cathode electrode. The first NW, the first PW and the second PW may overlap the first NBL.

The first deep trench and the second deep trench may be in direct contact with the first NBL.

The semiconductor device may further include a buried insulating layer formed below the Schottky diode.

The first PW and the first P+ region may be electrically connected to a ground electrode.

Effects which may be obtained by the present disclosure are not limited to the aforementioned effects, and other technical effects not described above may be evidently understood by a person having ordinary skill in the art to which the present disclosure pertains from the following description.

### BRIEF DESCRIPTION OF THE DRAWINGS

FIG. 1 illustrates a high voltage semiconductor device including a bootstrap Schottky diode according to an example of the present disclosure;

FIG. 2 illustrates a cross-sectional view of the high voltage semiconductor device including the bootstrap Schottky diode according to the example of the present disclosure and is a cross-sectional view taken along line A-A′ of FIG. 1;

FIG. 3 illustrates a cross-sectional view of a high voltage semiconductor device including a bootstrap Schottky diode according to another example of the present disclosure and is a cross-sectional view taken along line A-A′ of FIG. 1;

FIG. 4 illustrates a cross-sectional view of a high voltage semiconductor device including a bootstrap Schottky diode according to another example of the present disclosure and is a cross-sectional view taken along line A-A′ of FIG. 1;

FIG. 5 illustrates a cross-sectional view of a high voltage semiconductor device including a bootstrap Schottky diode according to another example of the present disclosure and is a cross-sectional view taken along line A-A′ of FIG. 1; and

FIG. 6 illustrates a circuit diagram for describing the operation of a high voltage semiconductor device according to the example of the present disclosure.

Other features and aspects will be apparent from the following detailed description, the drawings, and the claims.

### DETAILED DESCRIPTION

The features, advantages and method for accomplishment of the present disclosure will be more apparent from referring to the following detailed examples described as well as the accompanying drawings. However, the present disclosure is not limited to the example to be disclosed below and is implemented in different and various forms. The examples bring about the complete disclosure of the present disclosure and are only provided to make those skilled in the art fully understand the scope of the present disclosure. The present disclosure is just defined by the scope of the appended claims. The same reference numerals throughout the disclosure correspond to the same elements.

What one component is referred to as being “connected to” or “coupled to” another component includes both a case where one component is directly connected or coupled to another component and a case where a further another component is interposed between them. Meanwhile, what one component is referred to as being “directly connected to” or “directly coupled to” another component indicates that a further another component is not interposed between them. The term “and/or” includes each of the mentioned items and one or more all of combinations thereof.

Terms used in the present specification are provided for description of only specific examples of the present disclosure, and not intended to be limiting. In the present specification, an expression of a singular form includes the expression of plural form thereof if not specifically stated. The terms “comprises” and/or “comprising” used in the specification is intended to specify characteristics, numbers, steps, operations, components, parts or any combination thereof which are mentioned in the specification, and intended not to exclude the existence or addition of at least one another characteristics, numbers, steps, operations, components, parts or any combination thereof.

While terms such as the first and the second, etc., can be used to describe various components, the components are not limited by the terms mentioned above. The terms are used only for distinguishing between one component and other components.

Therefore, the first component to be described below may be the second component within the spirit of the present disclosure. Unless differently defined, all terms used herein including technical and scientific terms have the same meaning as commonly understood by one of ordinary skill in the art to which the present disclosure belongs. Also, commonly used terms defined in the dictionary should not be ideally or excessively construed as long as the terms are not clearly and specifically defined in the present application.

A term “module” or “unit” used in the examples of the present disclosure means a hardware component such as software or a field programmable gate array (FPGA) or an application specific integrated circuit (ASIC), and the “unit” or “module” performs certain roles. However, “unit” or “module” is not limited to software or hardware. The “unit” or “module” may be configured to be positioned in an addressable storage medium or may be configured to regenerate one or more processors. Thus, as an example, the “unit” or “module” may include components such as software components, object-oriented software components, class components, and task components, processes, functions, properties, procedures, subroutines, segments of program code, drivers, firmware, microcode, circuitry, data, databases, data structures, tables, arrays, and variables. Functions provided within components and “unit” or “modules” may be separated into smaller numbers of components and “units” or “modules” or integrated into additional components and “unit” or “modules”.

Methods or algorithm steps described relative to some examples of the present disclosure may be directly implemented by hardware and software modules that are executed by a processor or may be directly implemented by a combination thereof. The software module may be resident on a RAM, a flash memory, a ROM, an EPROM, an EEPROM, a resistor, a hard disk, a removable disk, a CD-ROM, or any other type of record medium known to those skilled in the art. An exemplary record medium is coupled to a processor and the processor can read information from the record medium and can record the information in a storage medium. In another way, the record medium may be integrally formed with the processor. The processor and the record medium may be resident within an application specific integrated circuit (ASIC). The ASIC may be resident within a user's terminal.

Hereafter, an example of the present disclosure will be described in detail such that those skilled in the art to which the present disclosure belongs will embody the technical idea of the present disclosure with reference to the accompanying drawings. However, the present disclosure may be embodied in various forms and is not limited to the example described in the present specification.

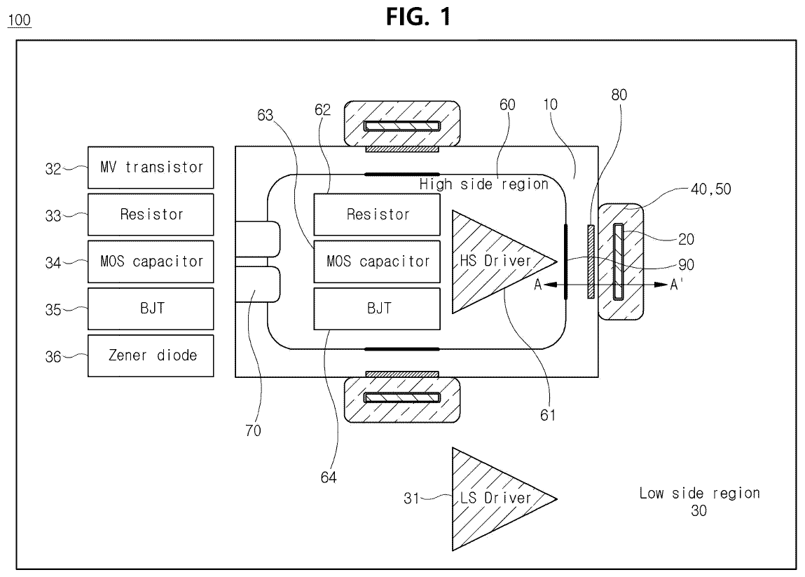

FIG. 1 illustrates a plan view of a high voltage semiconductor device including a bootstrap Schottky diode according to an example of the present disclosure.

Referring to FIG. 1, a high voltage semiconductor device 100 according to an example of the present disclosure may include a junction termination region 10 and a bootstrap Schottky diode 20. A sufficient voltage may be charged in a bootstrap capacitor (not shown) by a forward current of the bootstrap Schottky diode 20. Therefore, a sufficient voltage is applied to a gate of a high side MOSFET (not shown) to be operated, so that the high side MOSFET can be operated smoothly.

The high voltage semiconductor device 100 may further include a low side region 30. Also, in the low side (LS) region 30, a low side (LS) gate driver 31, a medium voltage (MV) transistor 32, a resistor 33, a metal-oxide-semiconductor (MOS) capacitor 34, a bipolar junction transistor (BJT) 35, and a Zener diode 36 may be disposed. Here, the low side gate driver 31 is a gate driver for operating a low side MOSFET (not shown).

The high voltage semiconductor device 100 according to the example may further include isolation region 40 and 50 surrounding the bootstrap Schottky diode 20. The isolation region 40 and 50 may be formed in a shape that completely surrounds the bootstrap Schottky diode 20 in order to protect the bootstrap Schottky diode 20 from a high voltage. This is because the bootstrap Schottky diode 20 has a structure that is vulnerable to a high voltage stress of the high side region 60. The greater widths of the isolation region 40 and 50, the more advantageous it may be to protect the bootstrap Schottky diode 20 from the high voltage stress. As shown in FIG. 1, a plurality of the bootstrap Schottky diodes 20 surrounded by the isolation region 40 and 50 may be disposed, or only one bootstrap Schottky diode 20 may be disposed when a sufficient forward current is generated. However, the bootstrap Schottky diode 20 is not limited to this.

The high voltage semiconductor device 100 according to the example may further include a high side (HS) region 60. In the high side region 60, a high side (HS) gate driver 61, a resistor 62, and a metal-oxide-semiconductor (MOS) capacitor 63, a bipolar junction transistor (BJT) 64 may be disposed. Here, the high side gate driver 61 is a gate driver for operating the high side MOSFET (not shown).

In the high voltage semiconductor device 100 according to the example, a level shifter 70 formed to overlap the junction termination region 10 and extend to the high side region 60 may be disposed.

The high voltage semiconductor device 100 according to the example may further include a source region 80 and a drain region 90. The source region 80 may be formed between the junction termination region 10 and the isolation region 40 and 50. The drain region 90 may be formed between the junction termination region 10 and the high side region 60. The source region 80 may be electrically connected to a cathode region (not shown) of the bootstrap Schottky diode 20. The forward current of the bootstrap Schottky diode 20 may be transmitted to the high side region 60 through a channel formed between the source region 80 and the drain region 90.

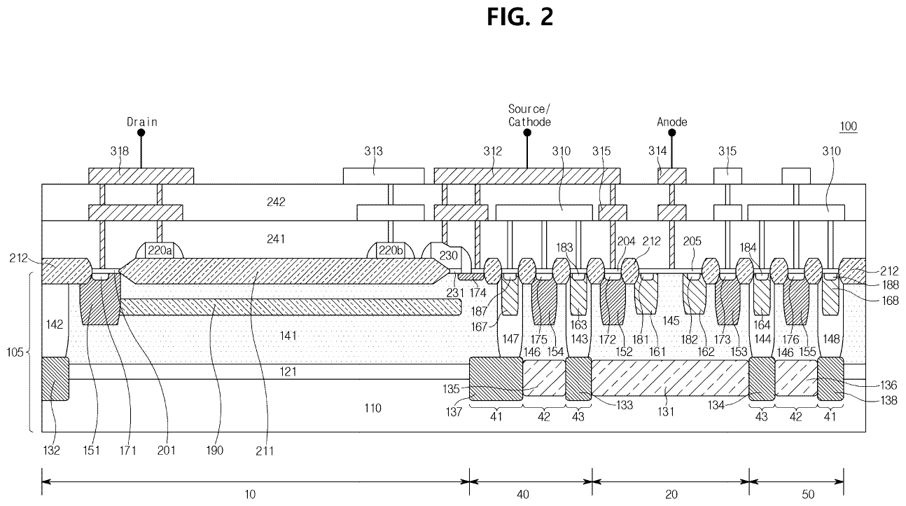

FIG. 2 illustrates a cross-sectional view of the high voltage semiconductor device including the bootstrap Schottky diode according to the example of the present disclosure and is a cross-sectional view taken along line A-A′ of FIG. 1.

Referring to FIG. 2, the high voltage semiconductor device 100 may include the junction termination region 10, the bootstrap Schottky diode 20 and the isolation regions 40 and 50. The junction termination region 10 may be formed to be spaced apart from the bootstrap Schottky diode 20 by the isolation regions 40 and 50. The isolation regions 40 and 50 completely surround the bootstrap Schottky diode 20.

According to the example, in the junction termination region 10, a low concentration first conductivity type (hereinafter, referred to as P-type) semiconductor substrate or a low concentration second conductivity type (hereinafter, referred to as N-type) semiconductor substrate 110 may be prepared in a substrate 105. In the example of the present disclosure, the p-type semiconductor substrate (P-sub) 110 will be described as an example. An n-type or p-type epitaxial layer 121 may be formed on the P-sub 110 in the junction termination region 10. In the example of the present disclosure, the n-type epitaxial layer (n-epi) 121 will be described as an example. A deep n-type well (DNW) 141 may be formed on the n-epi 121 in the junction termination region 10. The DNW 141 may be formed by ion implantation of n-type dopants and a high-temperature drive-in annealing process. The DNW 141 may be formed at a low concentration in order to have a high breakdown voltage, and may have a concentration that is 1 to 2 order less than a doping concentration of a n-type buried layer (NBL) 131. The DNW 141 having a long horizontal length may be designed to withstand a high voltage stress, for example, 600 V, and is not limited thereto.

According to the example, in the junction termination region 10, a p-type implanted top layer (P-TOP) 190 may be formed in the DNW 141. The P-TOP 190 may function as a gate. A field oxide (FOX) 211 may be formed on the P-TOP 190. Here, the P-TOP 190 and the FOX 211 may be formed to be spaced apart from each other at a predetermined distance. However, in another example, the P-TOP 190 and the FOX 211 may be formed in contact with each other.

According to the example, in the junction termination region 10, an n-type drain well region 151 may be formed in the DNW 141. A highly doped n-type drain (N+ drain) region 171 may be formed in the drain well region 151. A drain electrode 318 may be formed to electrically connect the N+ drain region 171. The drain electrode 318 in the junction termination region 10 may be electrically connected to the second power terminal Vb (not shown). Also, the bootstrap capacitor CB (not shown) connected to the second power terminal Vb may be placed.

A highly doped n-type source (N+ source) region 174 may be formed in the DNW 141. An insulating layer 231 may be formed between the N+ source region 174 and N+ drain region 171. A source field plate 230 may be formed on the insulating layer 231. Here, the N+ source region 174 may be formed to overlap the insulating layer 231 and the source field plate 230. A silicide layer 201 may be formed in contact with the N+ drain region 171 and the N+ source region 174. The silicide layer 201 may include one of CoSi2, TiSi2, PtSi2, or NiSi. A source/cathode electrode 312 may be formed to electrically connect the N+ source region 174 and the source field plate 230.

According to the example, in the junction termination region 10, a first field plate 220a and a second field plate 220b may be formed on the FOX 211. The first field plate 220a and the second field plate 220b may comprise a poly-silicon material. The first field plate 220a is electrically connected to the drain electrode 318 and may have the same potential as that of the drain electrode 318. The first field plate 220a may be called as a drain field plate. The second field plate 220b is electrically connected to a field plate electrode 313 which may have a ground potential. The first field plate 220a and the second field plate 220b may all serve to reduce a peak electric field. That is, the components act to help the surface electric field concentrated on the surface of the substrate 105 spread uniformly in the direction of the P-sub 110. It is advantageous to drive the high voltage semiconductor device 100 according to the example of the present disclosure at a high voltage.

Also, a p-type buried layer (PBL) 132 and a deep p-type well (DPW) 142 may be formed adjacent to the drain well region 151 to electrically isolate the junction termination region 10 from a peripheral circuit area (not shown) present in the high side region 60. The PBL 132 and the DPW 142 may be formed under the FOX 212.

According to the example, the junction termination region 10 can function as a depletion mode MOSFET device. In general, the depletion mode MOSFET device is known as a normally-on device. Compared to an enhancement mode MOSFET which is generally known as a normally-off device, the depletion mode MOSFET is in an on-state when a gate-source (VGS) voltage is zero. That is, the depletion mode MOSFET is in a general turned-on state.

In the bootstrap Schottky diode 20, a first n-type buried layer (NBL) 131 may be formed on the P-sub 110 by performing an ion implantation with n-type dopants into the P-sub 110. The n-epi 121 may be grown after the first NBL 131 is formed. Since the n-epi 121 is formed at a high temperature, the dopants in the first NBL 131 are diffused into the n-epi 121 or the P-sub 110, so that the width of the first NBL 131 may increase up and down. That is, the dopants of the first NBL 131 are diffused in both directions, and the thickness resulting from the diffusion of the dopants of the first NBL 131 may become greater than the thickness formed by initial ion implantation. The first NBL 131 may be formed in order to reduce leakage current of the bootstrap Schottky diode 20.

The DNW 145 may be formed on the first NBL 131 in the bootstrap Schottky diode 20. The DNW 145 in the bootstrap Schottky diode 20 may be formed simultaneously with the DNW 141 in the junction termination region 10. A first PW 161 and a second PW 162 may be formed in the DNW 145. The first PW 161 and the second PW 162 may be also formed on the first NBL 131. A first P-type highly doped (P+) region 181 and a second P+ region 182 may be respectively formed in the first PW 161 and the second PW 162. Each of the first PW 161 and the second PW 162 may be formed to surround a bottom corner region of the FOX 212, resulting in reducing an electric field concentrated in bottom corner region of the FOX 212. A high electric field may be generally formed around the bottom corner region, because a high electric stress may be concentrated on the bottom corner region of the FOX 212. Thus, the first PW 161 and the second PW 162 surrounding the bottom corner region of the FOX 212 may be helpful for improving a breakdown voltage of the bootstrap Schottky diode 20.

A first NW 152 and a second NW 153 may be formed in the DNW 145 to form a cathode region. The first NW 152 and the second NW 153 may be also formed on the first NBL 131. The first NW 152, the second NW 153, the first PW 161 and the second PW 162 may overlap the first NBL 131. Each doping concentration of the first NW 152 and the second NW 153 may be lower than that of the first NBL 131. A first N+ region 172 and a second N+ region 173 may be respectively formed in first NW 152 and the second NW 153 for ohmic contact formation. A silicide layer 204 may be formed on each of the first/second N+ regions 172 and 173. A cathode electrode 315 may be formed on the silicide layer 204. The cathode electrode 315 may be electrically connected to the first NW 152 and the second NW 153. The cathode electrode 315 may be also electrically connected to the source/cathode electrode 312. A forward current of the bootstrap Schottky diode 20 may pass through the cathode electrode 315 and the source/cathode electrode 312 and be transmitted to the junction termination region 10.

A Schottky barrier 205 may be formed on the DNW 145. The Schottky barrier 205 may include a silicide layer such as CoSi2, TiSi2, PtSi2, or NiSi, etc. The Schottky barrier 205 may be in direct contact with the first PW 161, the second PW 162, the first P+ region 181 and the second P+ region 182. An anode electrode 314 may be formed to electrically connect the Schottky barrier 205. Here, the anode electrode 314 may be electrically connected to a driving power circuit and may receive a driving voltage Vcc. The forward current may start from the anode electrode 314 by receiving the driving voltage Vcc, and may pass through the Schottky barrier 205, the DNW 145, the first NW 152, the first N+ region 172, the silicide layer 204, the cathode electrode 315, and the source/cathode electrode 312, and finally to the N+ source region 174 in the junction termination region 10.

According to the example, the driving power circuit may be arranged adjacent to the bootstrap Schottky diode 20 in order that the bootstrap Schottky diode 20 receives the driving voltage Vcc (not shown). The bootstrap Schottky diode 20 may be electrically connected to the driving power circuit through the anode electrode 314. The driving power circuit may supply the driving voltage Vcc to the anode electrode 314. The driving voltage Vcc may be a low voltage of about 10-30 V, but is not limited thereto. The bootstrap Schottky diode 20 may transmit a forward bias current from the anode electrode 314 to the junction termination region 10 through the cathode electrode 315 and the source/cathode electrode 312.

The isolation regions 40 and 50 may comprise PNP guard ring structure comprising a first p-type guard ring 41, an n-type guard ring 42, and a second p-type guard ring 43. The n-type guard ring 42 may be located between the first p-type guard ring 41 and second p-type guard ring 43. The PNP guard ring structure 41, 42 and 43 is shown as being two separate forms in a cross-sectional view, so the PNP guard ring structure is actually connected to each other in a circular form.

The first p-type guard ring 41 may include a first PBL 137 or 138 formed on the P-sub 110; a first DPW 147 or 148 formed on the first PBL 137 or 138; a PW 167 or 168 formed in the first DPW 147 or 148; and a P+ region 187 or 188 formed in the PW 167 or 168. The first p-type guard ring 41 may surround the n-type guard ring 42.

The first PBL 137 may be formed to extend further towards the junction termination region 10 than the first DPW 147 or PW 167 in the first p-type guard ring 41. As the first PBL 137 and the P-TOP 190 become closer to each other, a breakdown voltage may be increased in the high voltage semiconductor device 100.

Each of the first p-type guard ring 41 and the P-TOP 190 may be electrically connected to a ground potential. A high voltage around 600V may be applied to the drain electrode 318. The high voltage around 600V may be decreased due to a long distance of the DNW 141. Additionally, a pinch-off may occur between the P-TOP 190 and the first DPW 147 of the first p-type guard ring 41. Therefore, the high voltage may be blocked by the pinch-off.

The n-type guard ring 42 may include a second NBL 135 or 136 formed on the P-sub 110; a third NW 154 or 155 formed on the second NBL 135 or 136; and a N+ region 175 or 176 formed in the NW 154 or 155. The second NBL 135 or 136 of the n-type guard ring 42 may be formed simultaneously with the first NBL 131 of the bootstrap Schottky diode 20 in the manufacturing process. The n-type guard ring 42 may surround the second p-type guard ring 43.

The second p-type guard ring 43 may include a second PBL 133 or 134 formed on the P-sub 110; a DPW 143 or 144 formed on the second PBL 133 or 134; a PW 163 or 164 formed in the DPW 143 or 144; and a P+ region 183 or 184 formed in the PW 163 or 164. The second p-type guard ring 43 may surround the bootstrap Schottky diode 20.

The first PBL 137 or 138, the second NBL 135 or 136, and the second PBL 133 or 134 may be formed in parallel with each other. The first PBL 137 adjacent to the junction termination region 10 has a length greater than a length of the second PBL 133.

The PNP guard ring structure 41, 42 and 43 comprising the first p-type guard ring 41, the n-type guard ring 42, and the second p-type guard ring 43 are all connected to a ground electrode 310 and may receive a ground voltage. The PNP guard ring structure 41, 42 and 43 can reduce the leakage current of the bootstrap Schottky diode 20. When the bootstrap Schottky diode 20 is turned on, a forward current by the bootstrap Schottky diode 20 may be generated. Also, leakage current may occur at the same time. However, the leakage current can be sufficiently blocked by the PNP guard ring structure 41, 42 and 43. This is because the PNP guard ring structure 41, 42 and 43 can absorb floating electrons or hole carriers.

According to the example, the high voltage semiconductor device 100 may further include a first interlayer insulating layer 241 and a second interlayer insulating layer 242.

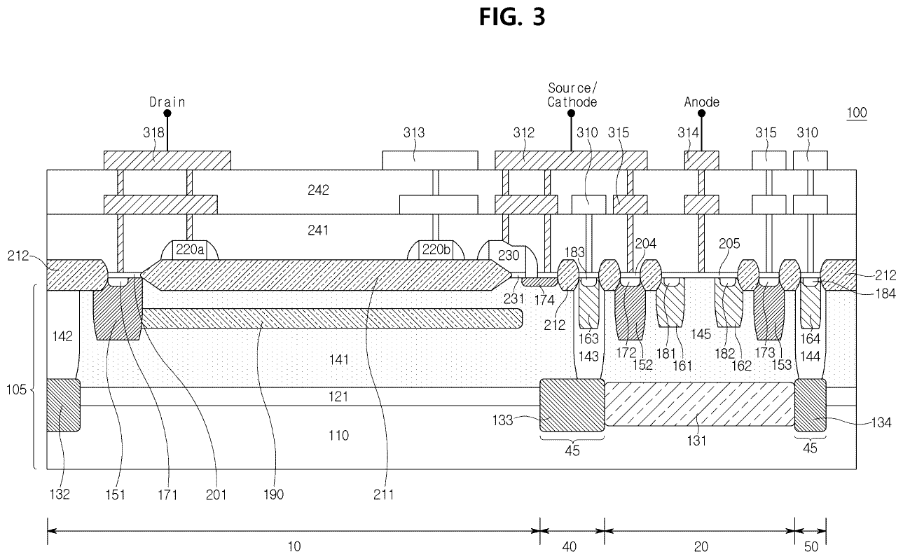

FIG. 3 illustrates a cross-sectional view of a high voltage semiconductor device including a bootstrap Schottky diode according to another example of the present disclosure.

Referring to FIG. 3, the isolation region 40 and 50 according to another example may include only one p-type guard ring 45 to reduce a chip size of the high voltage semiconductor device 100. Here, the one p-type guard ring 45 may include the PBL 133 or 134, a DPW 143 or 144, a PW 163 or 164, and a P+ region 183 or 184. Here, the PBL 133 or 134 may be in direct contact with the first NBL 131 in the bootstrap Schottky diode 20. As compared with the PNP guarding structure 41, 42 and 43 of the FIG. 2, the only one p-type guard ring 45 may remain in the isolation region 40 and 50.

The PBL 133 may be formed to extend further towards the junction termination region 10 than the DPW 143. This intends to cause the PBL 133 to be placed closer to the P-TOP 190. As the P-TOP 190 and the PBL 133 becomes closer to each other, a breakdown voltage may be increased in the high voltage semiconductor device 100.

A high voltage around 600V may be applied to the drain electrode 318. In that case, the high voltage may be decreased by the long DNW 141. Further, a pinch-off phenomenon may occur between the P-TOP 190 and the first DPW 147 of the one p-type guard ring 45. Thus, the high voltage does not reach the bootstrap Schottky diode 20. Then, the bootstrap Schottky diode 20 may be protected by the p-type guard ring 45 and the P-TOP 190.

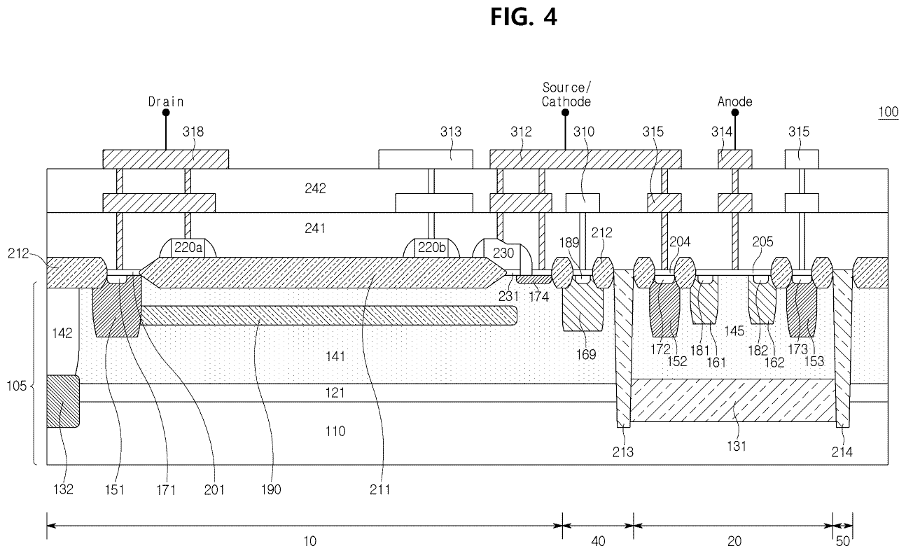

FIG. 4 illustrates a cross-sectional view of a high voltage semiconductor device including a bootstrap Schottky diode according to further another example of the present disclosure.

Referring to FIG. 4, the isolation region 40 and 50 may comprise a first deep trench 213 and a second deep trench 214 surrounding the bootstrap Schottky diode 20. The first and second deep trenches 213 and 214 may replace the PNP guard ring structure 41, 42 and 43 in FIG. 2 or the one p-type guard ring 45 in FIG. 3. The first and second deep trenches 213 and 214 may be formed by filling with an insulating layer. The first and second deep trenches 213 and 214 may significantly reduce the leakage current coming from the bootstrap Schottky diode 20 than the PNP guard ring structure 41, 42 and 43 illustrated in FIG. 2. The first and second deep trenches 213 and 214 may be in direct contact with the first NBL 131, and may reach the P-sub 110 by passing through the first NBL 131.

According to the example, the isolation region 40 may further comprise a PW 169 and a P+ region 189 in the DNW 141 formed between the N+ source region 174 and the first deep trench 213. The PW 169 and the P+ region 189 may be electrically connected to the ground electrode 310. When a high voltage around 600V is applied to the drain electrode 318, a pinch-off phenomenon may occur between the PW 169 and the P-TOP 190. The high voltage may be blocked by the PW 169 and the P-TOP 190, so the bootstrap Schottky diode 20 may be protected from the high reverse bias voltage.

According to the example, in the junction termination region 10, the source field plate 230 may be formed on the insulating layer 231. The first field plate 220a and the second field plate 220b may be formed on the FOX 211. Since the detailed descriptions of the above components are the same as those described in FIG. 2, they will be omitted.

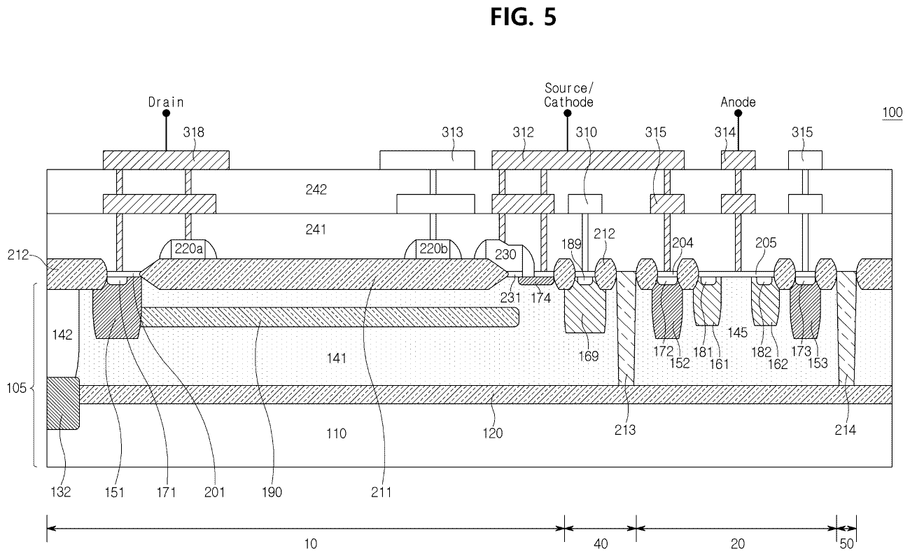

FIG. 5 illustrates a cross-sectional view of a high voltage semiconductor device including a bootstrap Schottky diode according to another example of the present disclosure.

Referring to FIG. 5, the isolation region 40 and 50 may comprise a first deep trench 213 and a second deep trench 214 surrounding the bootstrap Schottky diode 20. The isolation region 40 may further comprise a PW 169 and a P+ region 189 in the DNW 141 formed between the N+ source region 174 and the first deep trench 213.

The high voltage semiconductor device 100 according to the example may include a buried insulating layer 120 on the P-sub 110. An oxide layer may be used as the buried insulating layer 120. Thus, the substrate 105 may have a silicon on insulator (SOI) structure. A plurality of NBL and PBL in FIG. 2 may be replaced by buried insulating layer 120. Thus the first and second deep trenches 213 and 214 may directly contact the buried insulating layer 120. The bootstrap Schottky diode 20 may be separated from the P-sub 110 by the buried insulating layer 120. The bootstrap Schottky diode 20 may be surrounded by the first and second deep trenches 213 and 214 and the buried insulating layer 120. In this case, little leakage current may flow. Other elements are the same as those described in FIG. 2 or FIG. 3, so detailed descriptions will be omitted.

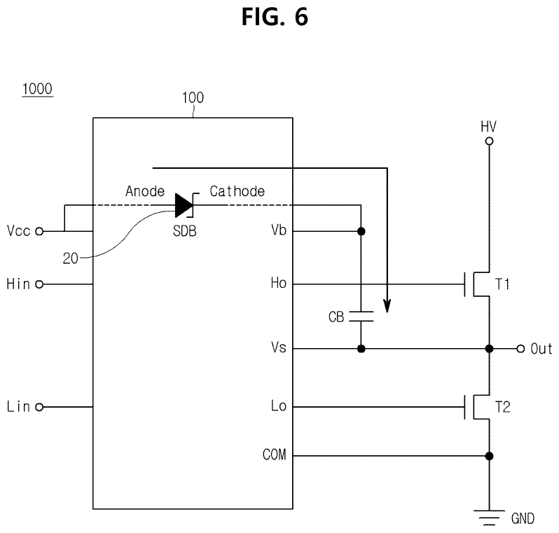

FIG. 6 illustrates a circuit diagram for describing the operation of a high voltage semiconductor device according to the example of the present disclosure.

Referring to FIG. 6, a high voltage gate driver integrated circuit 1000 may include the high voltage semiconductor device 100, the bootstrap Schottky diode SDB 20, the bootstrap capacitor CB, and a first and second power transistors T1 and T2.

The first power transistor T1 is provided between a high voltage HV and an output terminal (Out), so that the drain may be electrically connected to the high voltage HV and the source may be electrically connected to the output terminal (Out). The gate of the first power transistor T1 may be electrically connected to a high voltage driving output terminal (Ho) of the high voltage semiconductor device 100, and the first power transistor T1 may be turned on/off by the voltage output from the high voltage driving output terminal (Ho). When the first power transistor T1 is turned on, the high voltage HV can be output to the output terminal (Out).

The second power transistor T2 is provided between a ground GND and the output terminal (Out), so that the drain may be electrically connected to the output terminal (Out) and the source may be electrically connected to the ground GND. The gate of the second power transistor T2 may be electrically connected to a low voltage driving output terminal (Lo) of the high voltage semiconductor device 100, and the second power transistor T2 may be turned on/off by the voltage output from the low voltage driving output terminal (Lo). When the second power transistor T2 is turned on, the ground GND can be output to the output terminal (Out).

The source of the first power transistor T1 and the drain of the second power transistor T2 may be electrically connected to the output terminal (Out). Also, the output terminal (Out) may be electrically connected to a first power terminal Vs of the high voltage semiconductor device 100. The output terminal (Out) may be electrically connected to a load (Load).

The high voltage semiconductor device 100 may output a high voltage control signal that controls the operation of the first power transistor T1 through the high voltage driving output terminal (Ho) in response to a logic signal input through a high voltage input terminal (Hin).

The high voltage semiconductor device 100 may output a low voltage control signal that controls the operation of the second power transistor T2 through the low voltage driving output terminal (Lo) in response to a logic signal input through a low voltage input terminal (Lin).

The first power transistor T1 and the second power transistor T2 may be controlled not to be turned on at the same time. For example, while the first power transistor T1 is controlled to be turned on, the second power transistor T2 may be controlled to be turned off. Alternatively, while the first power transistor T1 is controlled to be turned off, the second power transistor T2 may be controlled to be turned on.

The bootstrap Schottky diode SDB 20 may be placed within the high voltage semiconductor device 100, but may also be placed outside the high voltage semiconductor device 100 during the design process. The bootstrap Schottky diode SDB 20 and the bootstrap capacitor CB may be electrically connected in series. The anode of the bootstrap Schottky diode SDB 20 may be electrically connected to a driving power supply that supplies the driving voltage Vcc, and one end of the bootstrap capacitor CB may be electrically connected to the output terminal (Out). Also, the cathode of the bootstrap Schottky diode SDB 20 and the other end of the bootstrap capacitor CB are connected to the second power terminal Vb, so that power for the control signal output to the high voltage driving output terminal (Ho) can be supplied.

When the second power transistor T2 is turned on and the first power transistor T1 is turned off, the voltage applied to one end of the bootstrap capacitor CB becomes the ground GND, so that a forward voltage is applied to the bootstrap Schottky diode SDB 20 and a forward bias current flows. The forward bias current is transmitted to the bootstrap capacitor CB and charges the bootstrap capacitor CB, and the second power terminal Vb is supplied with a voltage obtained by subtracting the threshold voltage of the bootstrap capacitor CB from the driving voltage Vcc. For example, if the driving voltage Vcc is 25 V, the bootstrap capacitor CB can be charged with a voltage of about 25 V.

When the first power transistor T1 is turned on and the second power transistor T2 is turned off, the voltage applied to one end of the bootstrap capacitor CB becomes a high voltage HV, so that a reverse bias voltage is applied to the bootstrap Schottky diode SDB 20 and a reverse bias current is blocked by the bootstrap Schottky diode SDB 20. Here, a value obtained by adding the voltage charged in the bootstrap capacitor CB to the high voltage HV applied to the one end of the bootstrap capacitor CB is applied to the second power terminal Vb. For example, in a case where the high voltage HV is 600 V and the voltage Vcc is 25 V, if the voltage charged in the capacitor CB is about 25 V, a total voltage is 625 V may be applied to the gate of the first power transistor T1. Therefore, as the total voltage of 625 V is output to the high voltage driving output terminal (Ho), the voltage between the source and the gate of the first power transistor T1 is made to be higher than the threshold voltage, so that the first power transistor T1 can be stably operated.

The operation of the high voltage semiconductor device 100 will be briefly described below.

The high voltage semiconductor device 100 may output the low voltage control signal to the low voltage driving output terminal (Lo) in response to a signal input through the low voltage input terminal (Lin) and may turn on the second power transistor T2. In order to turn on the second power transistor T2, the voltage of the low voltage control signal output to the low voltage driving output terminal (Lo) may be higher than or equal to the driving voltage Vcc.

When the second power transistor T2 is turned on, the output terminal (Out) may output the ground GND. Here, in order to prevent the high voltage HV from being applied to the output terminal (Out) simultaneously with the ground GND, the first power transistor T1 must be turned off. Since the voltage at one end of the bootstrap Schottky diode SDB 20 connected to the output terminal (Out) is the ground GND, a positive voltage is applied to the bootstrap Schottky diode SDB 20, and the driving voltage Vcc is dropped by the threshold voltage through the bootstrap Schottky diode SDB 20 and then is supplied to the bootstrap capacitor CB to charge the bootstrap capacitor CB.

Next, the high voltage semiconductor device 100 may output the low voltage control signal to turn off the operation of the second power transistor T2. Also, the high voltage semiconductor device 100 may output the high voltage control signal to the high voltage driving output terminal (Ho) in response to a signal input through the high voltage input terminal (Hin) and may turn on the first power transistor T1. When the first power transistor T1 is turned on, the output terminal (Out) may output the high voltage HV. Here, in order to prevent the ground GND from being applied to the output terminal (Out) simultaneously with the high voltage HV, the second power transistor T2 must be turned off.

When the first power transistor T1 is turned on and the output terminal (Out) outputs the high voltage HV, the first power terminal Vs which is connected to the output terminal (Out) and has the same potential value may receive the high voltage HV. The second power terminal Vb may be applied with a voltage obtained by adding the voltage charged in the bootstrap capacitor CB and the high voltage HV of the output terminal (Out). The voltage applied to the second power terminal Vb may be about 600 V or more, but is not limited thereto.

A reverse bias voltage may be applied to the bootstrap Schottky diode SDB 20 by the high voltage applied to the second power terminal Vb. When a reverse bias current due to the reverse bias voltage enters a low power drive circuit elements located on the anode side of the bootstrap Schottky diode SDB 20, low power drive circuit elements (the low side (LS) gate driver 31, the medium voltage (MV) transistor 32, the resistor 33, the metal-oxide-semiconductor (MOS) capacitor 34, bipolar junction transistor (BJT) 35, the Zener diode 36, etc., shown in FIG. 1) may be destroyed.

Therefore, the bootstrap Schottky diode SDB 20 is necessary to block the reverse bias current caused by the reverse bias voltage. In particular, the bootstrap Schottky diode SDB 20 must have a high withstand voltage such that the reverse bias current can be sufficiently blocked even if a high voltage of 600 V or more is applied by the reverse bias voltage.

As described in FIGS. 2 to 5, in order to protect the bootstrap Schottky diode SDB 20, the isolation region surrounding the bootstrap Schottky diode SDB 20 is required. The isolation region requires the PNP guard ring, one p-type guard ring, or the deep trenches. Also, the junction termination region may be required such that a high voltage of 600 V or more by the reverse bias voltage can be reduced, and several field plates may be required to reduce the electric field. Also, the first NBL 131 may be required to reduce the leakage current of the bootstrap Schottky diode SDB 20.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor device comprising:
a deep n-type well (DNW) formed in a junction termination region;
a source region and a drain region formed in the DNW;
a source electrode electrically connected to the source region;
a drain electrode electrically connected to the drain region;
an anode electrode formed in a Schottky diode;
a cathode electrode electrically connected to the source electrode; and
a first p-type guard ring surrounding the Schottky diode, the first p-type guard ring comprising a first p-type buried layer (PBL) and a first deep p-type well (DPW) formed on the first PBL,
wherein the first PBL extends further towards the junction termination region than the first DPW.

2. The semiconductor device of claim 1, further comprising:
a source field plate electrically connected to the source electrode;
a drain field plate electrically connected to the drain electrode;
a p-type top layer (P-TOP) formed in the DNW; and
a field oxide layer formed on the P-TOP.

3. The semiconductor device of claim 1, further comprising:
a first n-type buried layer (NBL) formed in the Schottky diode;
a first p-type well (PW) and a second PW formed on the first NBL;
a Schottky barrier formed on the first PW and the second PW and connected to the anode electrode; and
a first n-type well (NW) formed on the first NBL and connected to the cathode electrode,
wherein the first NW, the first PW and the second PW overlap the first NBL.

4. The semiconductor device of claim 1, further comprising:
an n-type guard ring disposed adjacent to the first p-type guard ring and comprising a second NBL and a third n-type well (NW) formed on the second NBL; and
a second p-type guard ring disposed adjacent to the n-type guard ring and comprising a second PBL and a second DPW formed on the second PBL.

5. The semiconductor device of claim 4, wherein the first PBL, the second NBL and the second PBL are formed in parallel with each other.

6. The semiconductor device of claim 4, wherein the first PBL has a length greater than a length of the second PBL.

7. A semiconductor device comprising:
a deep n-type well (DNW) formed in a junction termination region;
a source region and a drain region formed in the DNW;
a source electrode electrically connected to the source region;
a drain electrode electrically connected to the drain region;
an anode electrode formed in a Schottky diode;
a cathode electrode electrically connected to the source electrode;
a first deep trench and a second deep trench formed to surround the Schottky diode; and
a first p-type well (PW) and a first highly doped p-type (P+) region formed in the DNW and disposed between the source region and the first deep trench.

8. The semiconductor device of claim 7, further comprising:
a source field plate electrically connected to the source electrode;
a drain field plate electrically connected to the drain electrode;
a p-type top layer (P-TOP) formed in the DNW; and
a field oxide layer formed on the P-TOP.

9. The semiconductor device of claim 7, further comprising:
a first n-type buried layer (NBL) formed in the Schottky diode;
a first p-type well (PW) and a second PW formed on the first NBL;
a Schottky barrier formed on the first PW and the second PW and connected to the anode electrode; and
a first n-type well (NW) formed on the first NBL and connected to the cathode electrode,
wherein the first NW, the first PW and the second PW overlap the first NBL.

10. The semiconductor device of claim 9, wherein the first deep trench and the second deep trench are in direct contact with the first NBL.

11. The semiconductor device of claim 7, further comprising a buried insulating layer formed below the Schottky diode.

12. The semiconductor device of claim 7, wherein the first PW and the first P+ region are electrically connected to a ground electrode.
